(19) United States
(12) Patent Application Publication
(10) Pub. No.: US 2005/0190930 A1
(43) Pub. Date: Sep. 1, 2005

(54) Equalizer parameter control interface and method for parametric equalization

(76) Inventor: Robert J. Desiderio, Scottsdale, AZ (US)

Correspondence Address: QUARLES & BRADY LLP, RENAISSANCE ONE, TWO NORTH CENTRAL AVENUE, PHOENIX, AZ, 85004-2391, US

(21) Appl. No.: 10/791,238

(22) Filed: Mar. 1, 2004

(51) Int. Cl. H03G 5/00

(52) U.S. Cl. 381/103; 333/28 R

(57) ABSTRACT

A parametric equalizer has an audio filter with a plurality of electronic components. A first control knob (32) controls a center frequency of the audio filter. A second control knob (34) jointly controls signal level and bandwidth of the audio filter. The second control knob uses a potentiometer (120) with variable resistive elements on a common shaft (122). The variable resistive elements (56, 110) are coupled to nodes within the audio filter to jointly control the signal level and bandwidth. The control knobs are mounted to a control panel (30) for user access. A musical instrument, such as an electric bass guitar, generates audio signals, which are routed to a pre-amplifier (16) containing the parametric equalizer. The equalizer conditions the audio signals, which are boosted with a power amplifier to drive a speaker system.

### FIELD OF THE INVENTION

The present invention relates in general to equalizer control interfaces and, more particularly, to an equalizer using a simplified parameter control interface to provide parametric equalization.

### BACKGROUND OF THE INVENTION

Amplifiers are found in a myriad of applications for amplifying electrical signals. The amplifiers are also used to perform filtering and other analog signal processing. The electrical signal is typically representative of some information content or physical phenomena. For example, in the music industry, sound waves are generated by musical instruments. The sound is converted to electrical signals, which undergo various signal processing such as amplification, filtering, modulation, and distortion reduction to enhance the tonal quality. The electrical signals are used to drive speakers to faithfully reproduce the original sound from the musical instrument.

Electric guitars and electric bass guitars are well-known musical instruments. The artist plays the guitar and generates electric signals representative of the intended notes and chords. The electrical signals are routed through one or more audio amplifiers for pre-amplification, power amplification, filtering, and other signal processing. The processed signals then drive a speaker system to generate or reproduce the sound as music for the audience.

One form of electrical signal processing is known as equalization, which utilizes specific electronic amplification and filtering techniques. An equalizer often executes independent control over the signal level or amplitude, center frequency, and bandwidth of the filtering process. By adjusting the signal level and the center frequency and bandwidth of the equalizer filter, specific tonal qualities and audio content of the electric signal can be emphasized and de-emphasized. Equalization is used extensively with audio equipment and musical instruments to improve the subjective quality of sound reproduction.

One type of equalizer, known as a full parametric equalizer, is particularly useful and versatile in adjustment of all three equalization parameters, i.e., signal level, center frequency, and bandwidth. The parametric equalizer provides the ability to isolate or zero-in on a specific center frequency and adjust how much the amplitude level and frequency content of the signal is amplified (boost) or attenuated (cut) at that center frequency, as well as other frequencies around the center frequency. For example, the center frequency may be set to boost or cut signal levels in the bass or treble audio tone or sound range. The parametric equalizer can adjust the bandwidth (Q) or range of frequencies around the center frequency that are affected by the signal level boost or cut.

Several circuit topologies are well-known throughout the electronics industry for providing full parametric equalization. In most, if not all cases, the full parametric equalization has separate control mechanisms for the signal amplitude level boost or cut, center frequency, and bandwidth. That is, a first control knob may be dedicated to adjusting the amplitude level, a second control knob adjusts the center frequency of the equalizing filter, and a third control knob adjusts the bandwidth of the filter. Each control mechanism may have a continuous motion or be selectable in discrete steps.

There are many different implementations for the user interface to the parametric control. The user interface may take the form of separate rotary control knobs for each parameter. In another embodiment, linear slide controls are used to adjust each of the parameters. The linear slide controls can be mounted to move in the vertical or horizontal direction. Again, there is a specific and dedicated linear slide control for each parameter. In yet another implementation, the parametric controls are stacked on a common shaft to conserve panel space. The stacked controls use a common concentric-shaft potentiometer. An inner knob may control the center frequency, while an outer ring on the mutual shaft controls bandwidth. The inner knob and outer ring are separately adjusted to independently control center frequency and bandwidth. A third knob controls signal level.

When the artist is playing, the three separate controls for signal level, center frequency, and bandwidth, respectively, can be challenging to operate and difficult to fine tune. Most of the time, the artist's hands are busy playing the instrument. Some musicians find the technical concepts behind amplification, center frequency, and bandwidth adjustments to be more information than they want to know, difficult to comprehend, misunderstood, and just plain confusing. Some artists resort to randomly turning control knobs until the guitar sounds as good as they can make it; most just want to play without all the fussing around. Yet, many artists, especially serious performers, still want some degree of control over the audio signal and ultimate sound qualities.

A need exists for simple control mechanisms to adjust signal level, center frequency, and bandwidth in a parametric equalizer.

### SUMMARY OF THE INVENTION

In one embodiment, the present invention is a parametric equalizer comprising an audio filter having a plurality of electronic components. A first control mechanism has a variable resistive element coupled to a first node within the plurality of electronic components for controlling a center frequency of the audio filter. A second control mechanism has first and second commonly controlled variable resistive elements respectively coupled to second and third nodes within the plurality of electronic components. The first and second resistive elements jointly control signal level and bandwidth of the audio filter.

In another embodiment, the present invention is an audio system comprising a parametric equalizer having attributes determined by a plurality of control parameters. A first control interface is coupled for jointly controlling first and second control parameters of the parametric equalizer.

In yet another embodiment, the present invention is a method of controlling a parametric equalizer comprising the steps of providing a control interface having first and second variable elements which are jointly controlled, and controlling first and second control parameters of the parametric equalizer with the first and second variable elements.

### BRIEF DESCRIPTION OF THE DRAWINGS

FIG. 1 illustrates an electric guitar connected to an amplifier and speaker system;

FIG. 2 illustrates a two-knob control interface to the parametric equalizer;

FIG. 3 illustrates an alternate embodiment for the two-control interface to the parametric equalizer;

FIG. 4 is a block diagram of the parametric equalizer;

FIG. 5 illustrates the dual-potentiometer on a common shaft; and

FIG. 6 illustrates a waveform plot of various signal levels and bandwidths.

### DETAILED DESCRIPTION OF THE DRAWINGS

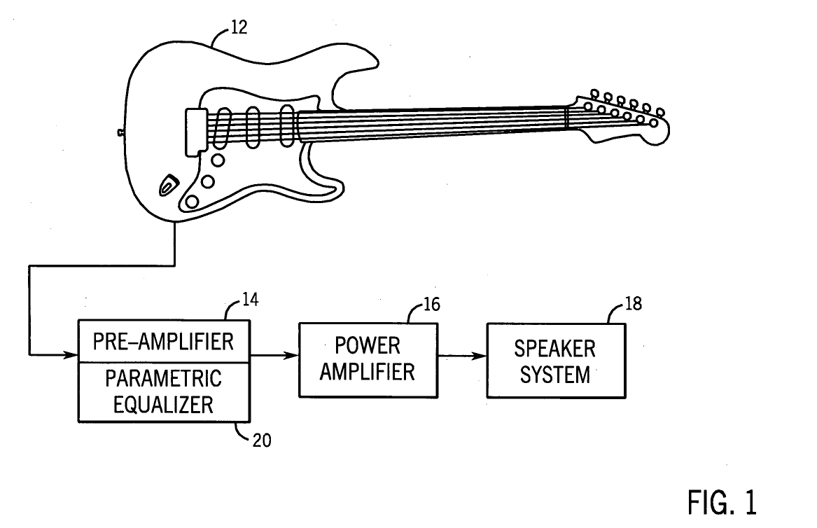

Referring to FIG. 1, a musical instrument such as electric bass guitar 12 has an audio output coupled to pre-amplifier 14. In other embodiments, the musical instrument may be an electric guitar, a violin, electric keyboard, audio microphone, or other instrument generating electric signals representative of sound content. Guitar 12 generates an electric signal representative of the produced sounds, which is sent to pre-amplifier 14 for signal conditioning. Pre-amplifier 14 provides amplification, filtering, and other signal processing. The output signal of pre-amplifier 14 is routed to power amplifier 16. Power amplifier 16 increases the power level and signal strength of the audio signal. The output of power amplifier 16 is coupled to speaker system 18 to reproduce the original sound.

To improve the audio tonal qualities and performance of guitar 12, the audio signal conditioning equipment, such as pre-amplifier 14 and power amplifier 16, uses a parametric equalizer for amplification and filtering functions. In the present discussion, parametric equalizer 20 is housed within pre-amplifier 16. Parametric equalizer 20 includes an audio filter, which can be implemented in a variety of designs and constructions. A low-pass audio filter will pass frequency components of the audio signal less than a predetermined cut-off frequency and attenuate or cut frequency components greater than the cut-off frequency. A high-pass audio filter will cut frequency components of the audio signal less than the predetermined cut-off frequency and pass frequency components greater than the cut-off frequency. A band-pass audio filter has upper and lower predetermined cut-off frequencies. The band-pass filter cuts frequency components of the audio signal which are less than the lower cut-off frequency or greater than the upper cut-off frequency. The band-pass filter passes frequency components of the audio signal between the lower and upper cut-off frequencies. A band-reject audio filter also has upper and lower predetermined cut-off frequencies. The band-reject filter passes frequency components of the audio signal which are less than the lower cut-off frequency or greater than the upper cut-off frequency. The band-reject filter cuts frequency components between the lower and upper cut-off frequencies.

The band-pass audio filter has three parametric controls: signal level, center frequency, and bandwidth. The band-pass filter has a signal amplitude level control. The band-pass filter has a center frequency control to select and adjust the center frequency of the pass band. The band-pass filter has a bandwidth or Q control to select and adjust the width of the frequency pass band. The lower cut-off frequency is the center frequency f_{c} less one-half of the bandwidth. The upper-cut-off frequency is the center frequency f_{c} plus one-half of the bandwidth. The narrower the bandwidth of the band-pass filter, the sharper the Q or frequency roll-off of the frequency response. A wider bandwidth of the band-pass filter widens the Q or frequency roll-off of the frequency response.

The band-reject audio filter has three similar parametric controls: signal level, center frequency, and bandwidth. The band-reject audio filter has a signal amplitude level control, center frequency control to select and adjust the center frequency of the rejection band, and Q control to select and adjust the width of the frequency rejection band. As with the band-pass filter, the narrower the bandwidth of the band-reject filter, the sharper the Q or frequency roll-off of the frequency response.

The artist or musician exercises direct control over the parameters of equalizer 20 through a user control panel or interface. The artist sets the signal amplitude level, center frequency, and Q of equalizer 20 to achieve specific tonal qualities, response, and performance of the sound. The user interface for the parametric control comes in a variety of forms and mechanisms. The interface mechanism may be rotary knobs, linear slide controls, discrete switches, or other mechanical control. The user interface to parametric equalizer 20 can be disposed on guitar 12, pre-amplifier 14, or other convenient control panel. The artist rotates the knobs, moves the slide controls, and flips the switches to select and adjust the desired parametric settings, which in turn define the attributes of equalizer 20 and control the overall audio response and sound quality. The audio feedback and listening pleasure resides with the artist and listeners.

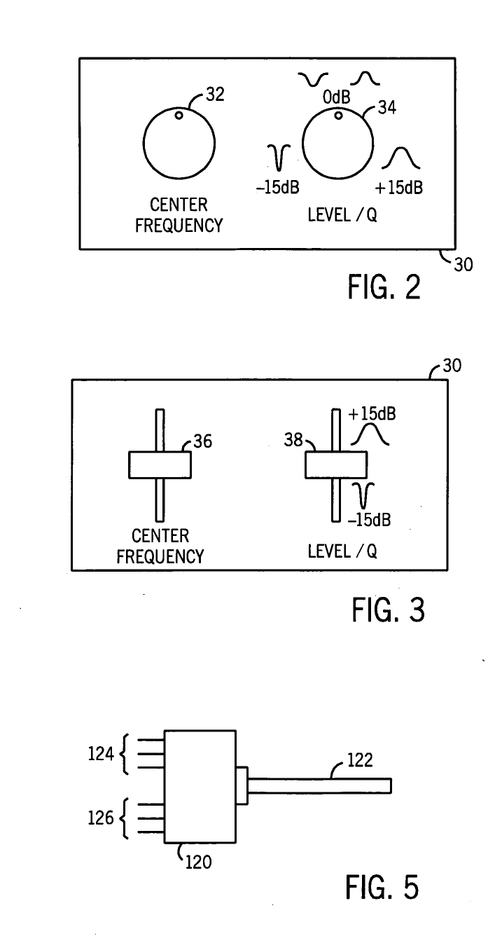

Turning to FIG. 2, the user interface to parametric equalizer 20 is shown as control panel 30 with control knob 32 and control knob 34. Control panel 30 can be mounted to guitar 12 or pre-amplifier 16 to give the artist convenient and ready access to the parametric control functions. Control knobs 32 and 34 are rotary knobs, which can be grasped and turned by hand, e.g., with thumb and index finger. Control panel 30 may be integrated into a larger and more comprehensive audio control panel operated by technician during a recording session, concert, or musical performance.

In one embodiment, control knob 32 connects to a dual potentiometer, which changes resistive or reactive impedances in the amplifier and/or audio filtering circuit to select and adjust the center frequency f, of parametric equalizer 20. Control knob 32 is turned to the left or counter-clockwise to decrease the center frequency of the audio filter and to the right or clockwise to increase the center frequency. Control knob 34 connects to a dual potentiometer, which changes resistive or reactive impedances in the amplifier and/or audio filtering circuit to select and adjust both the signal amplitude level and the bandwidth or Q of parametric equalizer 20. The parametric control functions of signal level and Q are jointly controlled by the same knob 34. Equalizer 20 provides ±15 dB of boost or cut at the extreme travel ranges of control knob 34. There is little or no boost or cut in the center position of knob 34.

Control knob 34 is turned to the left or counter-clockwise to decrease signal level and narrow the Q of the audio filter. At the extreme left of the travel range of knob 34, the signal level is −15 dB at the selected center frequency, and the Q has its narrowest setting as shown on the face of control panel 30. Control knob 34 is turned to the right or clockwise to increase signal level and widen the Q of the audio filter. At the extreme right of the travel range of knob 34, the signal level is +15 dB at the selected center frequency, and the Q has its widest setting as shown on the face of control panel 30. At 0 dB, the Q of the audio filter is mid-range, with a flat frequency response and little or no boost or cut.

In the design considerations of parametric equalizer 20, it is preferable to widen the Q when operating in boost mode and narrow the Q when operating in cut mode. In other words, as the signal amplitude level is amplified or boosted, the overall quality of sound tends to improve if the bandwidth of equalizer 20 is widened at the same time. When boosting the signal, the wider Q passes more frequency components of the amplified sound. On the other hand, as the signal amplitude level is attenuated or cut, then the overall quality of sound tends to improve if the bandwidth of equalizer 20 is narrowed at the same time. When cutting the signal, the narrower Q helps isolate and eliminate the problem frequency, hum, resonance, or other undesired responses. Both signal level and Q change concurrently and simultaneously, although the relative rates may be proportional or non-linear and the relative direction of change may be aligned or opposing.

In FIG. 3, control panel 30 uses linear slide controls 36 and 38 for controlling the equalizer parameters. Linear slide control 36 moves to the left or down to decrease the center frequency of the audio filter and to the right or up to increase the center frequency. Linear slide control 38 moves to the left or down to decrease the signal level and narrow the Q of the audio filter and to the right or up to increase signal level and widen the Q.

In another embodiment, equalizer 20 may be designed such that the Q is narrowed in boost mode and widened in cut mode. In another situation, signal level and center frequency may be controlled by the same electromechanical control mechanism, or center frequency and Q may be controlled together. For example, equalizer 20 may be designed such that the Q decreases as center frequency increases, or visa versa. Therefore, parametric equalizer 20 has a user interface that combines two or more parameter control functions, which are jointly controlled from a common electro-mechanical control mechanism, i.e., control knob 34.

Combining the signal level and Q control functions on the same control knob 34 to jointly control these parametric functions eliminates the requirement for the artist to physically and independently set each parameter function. Indeed, in the present embodiment, the artist no longer need be concerned with how to set the Q, or understand why the Q is set, or even be aware that the Q exists. The simplified user-interface using two control knobs to control three equalizer parameters reduces clutter on control panel 30 and frees up space for other features, or allows the area of control panel 30 reserved for parametric control to be reduced.

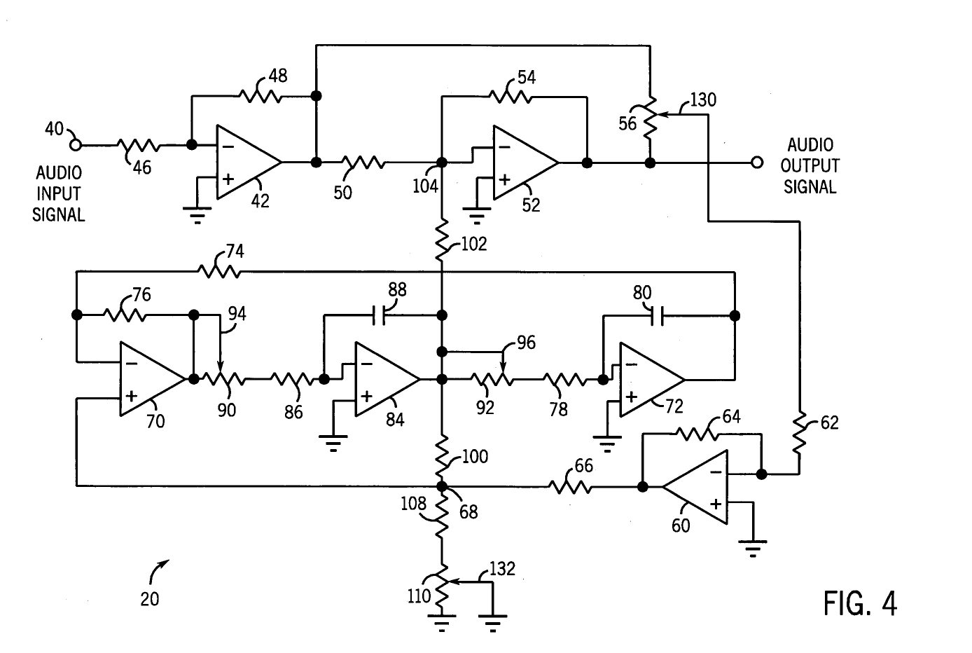

An audio filter portion of parametric equalizer 20 is shown with further detail in FIG. 4. The audio filter is configured as a state variable filter and provides high-pass, low-pass, and band-pass filter functions. The audio input signal is applied to terminal 40. Operational amplifier 42 and resistors 46 and 48 provide buffering and amplification of the audio input signal. The non-inverting input of amplifier 42 is coupled to ground potential. Resistor 50 is coupled between the output of amplifier 42 and the inverting input of amplifier 52. Operational amplifier 52 and resistor 54 provides amplification and summation. The non-inverting input of amplifier 52 is coupled to ground potential. The output of amplifier 52 is the audio output signal of the audio filter portion of parametric equalizer 20. Resistor 56 is coupled between the output of amplifier 42 and the output of amplifier 52 and includes a variable resistance tap point coupled to the inverting input of amplifier 60.

Operational amplifier 60 and resistors 62 and 64 function as an inverting amplifier with gain. The non-inverting input of amplifier 60 is coupled to ground potential. Resistor 66 is coupled between the output of amplifier 60 and summing node 68. Operational amplifier 70 is a differential amplifier, which amplifies the difference between the signal at summing node 68 and the output of operational amplifier 72. Resistors 74 and 76 set the gain of amplifier 70. Operational amplifier 72 is configured as a low-pass filter with resistor 78 and capacitor 80. Likewise, operational amplifier 84 is configured as a low-pass filter with resistor 86 and capacitor 88.

Amplifiers 70, 72, and 84, and associated passive components, operate as a band-pass state variable filter. Resistors 90 and 92 are variable resistance elements and are implemented with dual-potentiometer on a common shaft. Resistors 90 and 92 set the center frequency of the state variable filter. Turning the common shaft of the dual-potentiometer in the clockwise direction moves wiper arm 94 to the right, as shown in FIG. 4. The resistance between the output of amplifier 70 and the inverting input of amplifier 84 decreases. Turning the common shaft in the counter-clockwise direction moves wiper arm 94 to the left, as shown in FIG. 4, and causes the resistance between the output of amplifier 70 and the inverting input of amplifier 84 to increase. Turning the common shaft of the dual-potentiometer in the clockwise direction also moves wiper arm 96 to the right, as shown in FIG. 4. The resistance between the output of amplifier 84 and the inverting input of amplifier 72 decreases. Turning the common shaft in the counter-clockwise direction moves wiper arm 96 to the left and causes the resistance between the output of amplifier 84 and the inverting input of amplifier 72 to increase. Stated in other terms, turning the common shaft of the dual-potentiometer in the clockwise direction increases the center frequency of the audio filter, while turning the common shaft in the counter-clockwise direction decreases the center frequency of the audio filter.

Resistor 100 is coupled between the output of amplifier 84 and summing node 68. Resistor 102 is coupled between the output of amplifier 84 and summing node 104. The resistors allow-the currents to sum into the respective nodes. Resistors 108 and 110 are coupled between summing node 68 and ground potential.

Resistor 56 and resistor 110 are variable resistive elements with controllable resistance values. Resistors 56 and 110 are implemented with dual-potentiometer 120 having a common shaft 122, as shown in FIG. 5. Terminals 124 of potentiometer 120 are the three connection points for resistor 56. Terminals 126 of potentiometer 120 make up the three connection points for resistor 110. Resistors 56 and 110 are commonly controlled variable resistive elements; the common control being achieved with shaft 122. Turning common shaft 122 of dual-potentiometer 120 in the clockwise direction moves wiper arm 130 upward, as shown in FIG. 4. The resistance between the output of amplifier 42 and the inverting input of amplifier 60 decreases. Turning common shaft 122 in the counter-clockwise direction moves wiper arm 130 downward, as shown in FIG. 4, and causes the resistance between the output of amplifier 42 and the inverting input of amplifier 60 to increase. Turning common shaft 122 of the dual-potentiometer 120 in the clockwise direction moves wiper arm 132 downward, as shown in FIG. 4. The resistance between summing node 68 and ground increases. Turning common shaft 122 in the counter-clockwise direction moves wiper arm 132 upward and causes the resistance between summing node 68 and ground to decrease.

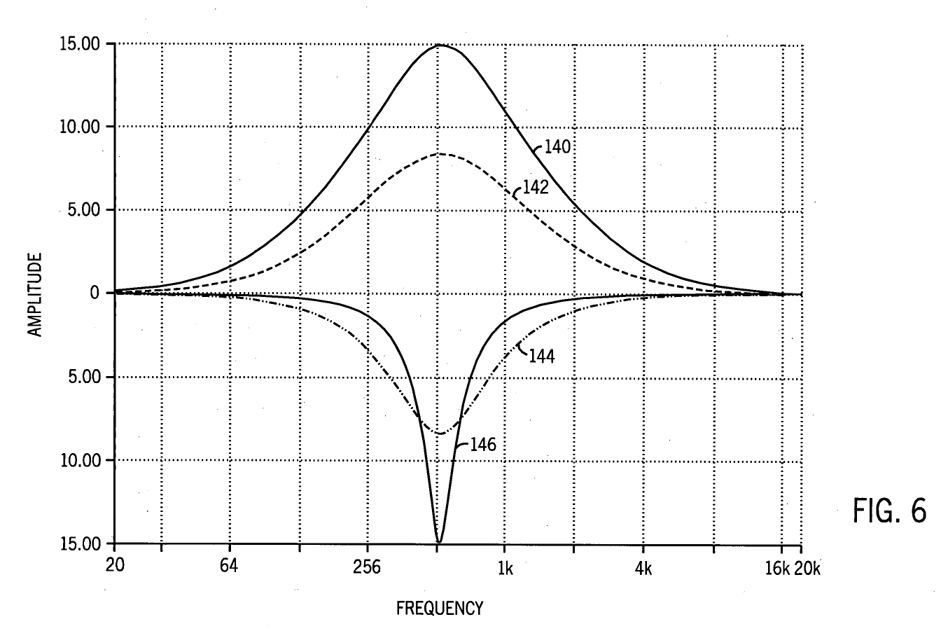

The operation of the audio filter portion of parametric equalizer 20 can be explained with the waveform plots shown in FIG. 6. The waveform plots illustrate signal amplitude versus frequency, with frequency control held constant. The Y-axis is expressed in decibels; the X-axis is expressed in units of frequency. As common shaft 122 of dual potentiometer 120 is turned in the clockwise direction, the resistance between the output of amplifier 42 and the inverting input of amplifier 60 decreases. The lower effective input resistance to amplifier 60, in relation to resistor 64, increases its gain. The overall gain of the audio filter increases. In addition, by turning common shaft 122 in the clockwise direction, the resistance between summing node 68 and ground increases. The higher resistance widens the bandwidth or Q of the audio filter. Therefore, the act of turning common shaft 122 in the clockwise direction simultaneously boosts the signal level and widens the bandwidth. The single act causes both parameter control functions to occur together and be jointly controlled. At the maximum clockwise travel range of dual-potentiometer 120, the frequency response of the audio filter is seen as plot 140 with maximum boost and maximum bandwidth.

From the maximum clockwise limit, as common shaft 122 of dual potentiometer 120 is turned in the counter-clockwise direction, the resistance between the output of amplifier 42 and the inverting input of amplifier 60 increases. The higher effective input resistance to amplifier 60, in relation to resistor 64, decreases its gain. The overall gain of the audio filter decreases. In addition, by turning common shaft 122 in the counter-clockwise direction, the resistance between summing node 68 and ground decreases. The lower resistance decreases bandwidth and sharpens the Q of the audio filter. Therefore, the act of turning common shaft 122 in the counter-clockwise direction simultaneously decreases the signal level and narrows the bandwidth. Plot 142 illustrates decreasing signal level and narrowing bandwidth. Plots 144 illustrate signal level cut and further narrowing of the frequency bandwidth. At the maximum counter-clockwise travel range of dual-potentiometer 120, the frequency response of the audio filter is seen as plot 146 with maximum cut and sharpest Q.

The dual-element potentiometer 120 with a single common shaft 122 provides simultaneous and joint control of both variable resistors 56 and 110. The dual-control allows two parameters, e.g., signal level and Q, of equalizer 20 to be commonly adjusted with a single motion. The dual-control simplifies the user interface. The artist can have control over the sound reproduction without having to separately adjust the equalizer Q. The equalizer Q changes in relation to adjustments made in the boost and cut.

Parametric equalizer 20 may be implemented with different orders and complexities of filters. In some embodiments, the multiple parametric functions, e.g. signal level and bandwidth, may be commonly controlled with one variable resistive element coupled to one node within the filter. A single control interface control the single resistive element, which in turn controls the multiple parametric functions. In other embodiments, the multiple parametric functions are controlled with three or more variable resistive elements coupled to respective multiple nodes within the filter. A single control interface still controls the multiple resistive elements, which in turn controls the multiple parametric functions.

Parametric equalizer 20 can be implemented with digital circuits, in which case the user interface is digitally controlled. In other embodiments, parametric equalizer 20 can be implemented with software and the user interface contained within the programming code. In each case, two or more parameters of the equalizer function are configured to change at the same time, with the same control motion or same control interface. As discussed above, the Q can be programmed to change with signal level. The equalizer having a common control interface to simultaneously change multiple parametric control parameters is applicable to many other analog and digital signal processing applications.

A person skilled in the art will recognize that changes can be made in form and detail, and equivalents may be substituted for elements of the invention without departing from the scope and spirit of the invention. The present description is therefore considered in all respects to be illustrative and not restrictive, the scope of the invention being determined by the following claims and their equivalents as supported by the above disclosure and drawings.

1. A parametric equalizer, comprising:
an audio filter having a plurality of electronic components;
a first control mechanism having a variable resistive element coupled to a first node within the plurality of electronic components for controlling a center frequency of the audio filter; and
a second control mechanism having first and second commonly controlled variable resistive elements respectively coupled to second and third nodes within the plurality of electronic components, wherein the first and second resistive elements jointly control signal level and bandwidth of the audio filter.

2. The parametric equalizer of claim 1, wherein the first control mechanism includes a potentiometer having a terminal coupled to the first node within the plurality of electronic components.

3. The parametric equalizer of claim 1, wherein the second control mechanism includes a potentiometer housing the first and second commonly controlled variable resistive elements, the first resistive element having a terminal coupled to the second node within the plurality of electronic components and the second resistive element have a terminal coupled to the third node within the plurality of electronic components.

4. The parametric equalizer of claim 1, wherein the first and second control mechanisms are mounted to a control panel for user access.

5. The parametric equalizer of claim 1, wherein the plurality of electronic components includes a gain amplifier, the first resistive element of the second control mechanism being coupled to an input of the gain amplifier for adjusting the signal level of the audio filer.

6. The parametric equalizer of claim 1, wherein the plurality of electronic components includes a summing node, the second resistive element of the second control mechanism being coupled to the summing node for adjusting the bandwidth of the gain amplifier.

7. An audio system, comprising:
a parametric equalizer having attributes determined by a plurality of control parameters; and
a first control interface coupled for jointly controlling first and second control parameters of the parametric equalizer.

8. The audio system of claim 7, wherein the parametric equalizer includes an audio filter having plurality of electronic components.

9. The audio system of claim 8, further including a second control interface coupled for controlling a third control parameter of the parametric equalizer.

10. The audio system of claim 9, wherein the second control interface includes a variable resistive element coupled to a first node within the plurality of electronic components.

11. The audio system of claim 9, wherein the third control parameter is a center frequency of the audio filter.

12. The audio system of claim 9, further including a control panel for mounting the first and second control interfaces.

13. The audio system of claim 8, wherein the first control interface includes first and second commonly controlled variable resistive elements respectively coupled to first and second nodes within the plurality of electronic components.

14. The audio system of claim 8, wherein the first control parameter is signal level of the audio filter and the second control parameter is bandwidth of the audio filter.

15. The audio system of claim 8, wherein the second control interface includes a potentiometer housing the first and second commonly controlled variable resistive elements, the first resistive element having a terminal coupled to a first node within the plurality of electronic components and the second resistive element have a terminal coupled to a second node within the plurality of electronic components.

16. The audio system of claim 7, further including a guitar for generating audio signals which are routed to the parametric equalizer.

17. The audio system of claim 16, further including a pre-amplifier coupled for receiving the audio signals from the guitar.

18. The audio system of claim 17, further including a power amplifier having an input coupled to an output of the pre-amplifier.

19. The audio system of claim 18, further including a speaker system having an input coupled to an output of the power amplifier.

20. The audio system of claim 7, further including a bass guitar for generating audio signals which are routed to the parametric equalizer.

21. The audio system of claim 20, further including a pre-amplifier coupled for receiving the audio signals from the bass guitar.

22. A signal processing circuit, comprising:
a filter;
a first variable resistor coupled to a first node within the filter for controlling a first parametric function of the filter; and
a second variable resistor coupled to a second node within the filter for controlling a second parametric function of the filter, wherein the first and second variable resistors are jointly controlled.

23. The signal processing circuit of claim 22, further including a potentiometer housing the first and second variable resistors on a common shaft.

24. The signal processing circuit of claim 22, wherein the first parametric function is signal level and the second parametric function is bandwidth.

25. A method of controlling a parametric equalizer, comprising:
providing a control interface having first and second variable elements which are jointly controlled; and
controlling first and second control parameters of the parametric equalizer with the first and second variable elements.

26. The method of claim 25, wherein the first and second variable elements are first and second variable resistors.

27. The method of claim 25, wherein the first and second resistors are housed with a potentiometer and controlled by a common shaft.

28. The method of claim 25, wherein the first control parameter is signal level of the parametric equalizer and the second control parameter is bandwidth of the parametric equalizer.
